(19) United States
(12) Patent Application Publication
(10) Pub. No.: US 2026/0123398 A1
(43) Pub. Date: Apr. 30, 2026

(54) SEMICONDUCTOR DEVICE INCLUDING A CAPACITOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Wen-Ling CHANG, Miaoli (TW); Li-Chung YU, Kaohsiung (TW); Yi-Shan HSIEH, Hsinchu (TW); Tzu-Ting LIU, Taoyuan (TW); Hsiang-Ku SHEN, Hsinchu (TW); Dian-Hau CHEN, Hsinchu (TW)

(21) Appl. No.: 19/064,980

(22) Filed: Feb. 27, 2025

Related U.S. Application Data
(60) Provisional application No. 63/713,631, filed on Oct. 30, 2024.

(51) Int. Cl. H01L 23/522; H01L 23/00; H01L 23/48; H10D 1/00; H10D 1/68

(52) U.S. Cl. CPC H10W 20/495; H10D 1/042; H10D 1/714; H10D 1/716; H10W 20/20; H10W 72/90

(57) ABSTRACT

In some embodiments, a semiconductor device is provided. The semiconductor device includes an interconnect structure disposed over a substrate, wherein the interconnect structure includes a conductive feature disposed in a dielectric layer; a first passivation layer disposed over the interconnect structure; a second passivation layer disposed over the etch stop layer; a plurality of holes and a plurality of trenches extending from an upper surface of the second passivation layer into the second passivation layer, wherein the trenches overlap the etch stop layer in a plan view; a first capacitor structure including a first conductive layer, a first insulating layer, and a second conductive layer disposed over the second passivation layer and extending into the holes; and a second capacitor structure including a third conductive layer, a second insulating layer, and a fourth conductive layer disposed over the second passivation layer and extending into the trenches.

### CROSS-REFERENCE TO RELATED APPLICATIONS

This application claims priority to U.S. Provisional Application Ser. No. 63/713,631 filed on Oct. 30, 2024, which is incorporated by reference in its entirety.

### BACKGROUND

Electronic equipment involving semiconductor devices are essential for many modern applications. Technological advances in materials and design have produced generations of semiconductor devices where each generation has smaller and more complex circuits than the previous generation. In the course of advancement and innovation, functional density (i.e., the number of interconnected devices per chip area) has generally increased while geometric size (i.e., the smallest component that can be created using a fabrication process) has decreased. Such advances have increased the complexity of processing and manufacturing semiconductor devices.

Capacitors are commonly embedded in integrated passive devices and used in place of ceramic capacitors to reduce the size of mobile devices, reduce the cost of mobile devices, increase the functionality of mobile devices, or any combination of the foregoing. To provide improved characteristics and performance of the capacitors, metal-insulator-metal (MIM) capacitor designs comprising a plurality of metal layers and dielectric layers in an interleaved pattern have recently been introduced. When the layers of the MIM capacitors are formed within a recess having a high aspect ratio, the manufacturing processes become complicated and hard to control. Accordingly, an improved MIM capacitor structure and manufacturing methods thereof are desired.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device including a device layer and an interconnect structure, in accordance with some embodiments.

FIG. 2 is a cross-sectional view of an interconnect structure of a semiconductor device, in accordance with some embodiments.

FIG. 3 illustrates a cross-sectional view of a semiconductor device including a an interconnect structure in a passivation structure, in accordance with some embodiments.

FIG. 4 is a scheme for illustrating regions for arranging capacitor structures in a unit area of a semiconductor device in a plan view, in accordance with some embodiments.

FIGS. 5A, 5B and 5C illustrate enlarged views of a hole-type capacitor, a trench-type capacitor, and a hybrid-type capacitor, respectively, in the regions illustrated in FIG. 4, in accordance with some embodiments.

FIGS. 6 to 12 illustrate cross-sectional views of intermediate stages in the manufacturing of a semiconductor device, in accordance with some embodiments.

FIG. 13 illustrates a cross-sectional view of a semiconductor device including capacitor structure in a passivation structure, in accordance with some embodiments.

FIG. 14 illustrates a cross-sectional view of a semiconductor device including capacitor structure in a passivation structure, in accordance with some embodiments.

FIG. 15 illustrates a cross-sectional view of a semiconductor device including capacitor structure in a passivation structure, in accordance with some embodiments.

FIG. 16 illustrates a cross-sectional view of a semiconductor device including capacitor structure in a passivation structure, in accordance with some embodiments.

FIG. 17 illustrates a cross-sectional view of a semiconductor device including capacitor structure in a passivation structure, in accordance with some embodiments.

FIG. 18 illustrates a cross-sectional view of a semiconductor package, in accordance with some embodiments.

FIG. 19 illustrates a cross-sectional view of a semiconductor device including a capacitor structure and a backside interconnect structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The apparatus may be otherwise oriented (rotated 90 degrees or at other orientations) and the spatially relative descriptors used herein may likewise be interpreted accordingly.

A semiconductor device including a capacitor structure is provided, in accordance with some embodiments. The semiconductor device may include hole-type capacitors and trench-type capacitors formed in a passivation structure over an interconnect structure. The hole-type capacitor includes layers extending into holes, and the trench-type capacitor includes layers extending into the trenches. The hole-type capacitors may generate less stress in the semiconductor device, and the trench-type capacitors may be disposed in areas with small dimensions. The passivation structure may include an etch stop layer being at least located where the trenches are to be formed. The etch stop layer may partially or completely resist the etch process for forming the trenches. As a result, although the etch process may have a greater etch rate in forming trenches than that in forming the holes, the trenches may be distant from and not damage the underlying interconnect structure when the holes reach to their desired depth. Accordingly, the semiconductor device can contain the hole-type capacitors and the trench-type capacitors simultaneously with improved manufacturing yield.

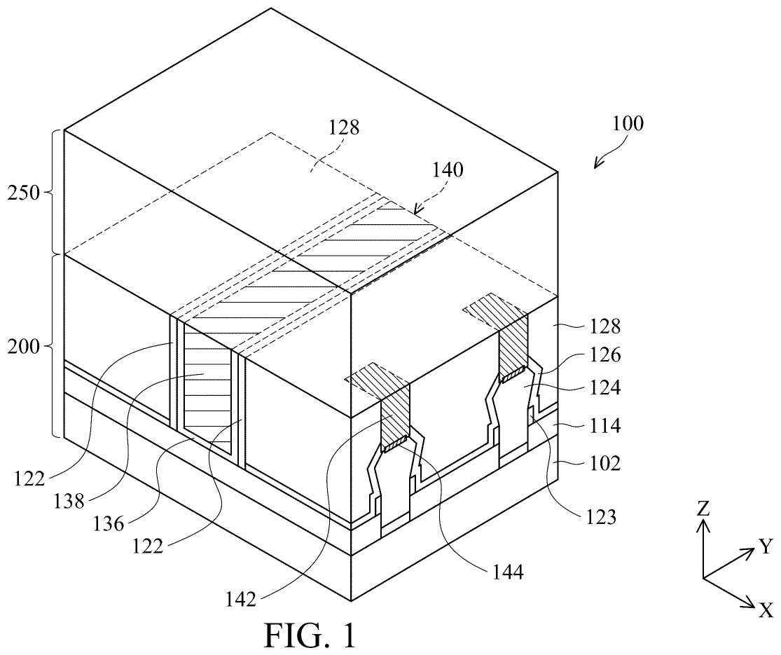

FIG. 1 is a perspective sectional view of a semiconductor device 100 including a device layer 200 and an interconnect structure 250. The device layer 200 includes a substrate 102 and one or more devices formed in or on the substrate 102. The substrate 102 may be a semiconductor substrate. In some embodiments, the substrate 102 includes a crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include various regions, including active regions and isolation regions. The active regions may be suitably doped with impurities (e.g., p-type or n-type impurities), for forming, for example, well regions.

As described above, the device layer 200 may include any suitable devices, such as transistors, diodes, imaging sensors, resistors, capacitors, inductors, memory cells, or a combination thereof. In some embodiments, the device layer 200 includes transistors, such as planar field effect transistors (FETs), FinFETs, nanostructure transistors, or other suitable transistors. The nanostructure transistors may include nanosheet transistors, gate-all-around (GAA) transistors, multi-bridge channel (MBC) transistors, or any transistors having the gate electrode surrounding the channels. An example of the device formed on the substrate 102 is a FinFET, which is shown in FIG. 1. The device layer 200 includes source/drain (S/D) regions 124 and gate stacks 140 (only one is shown in FIG. 1). Each gate stack 140 may be disposed between one or more S/D regions 124 serving as source regions and one or more S/D regions 124 serving as drain regions. For example, each gate stack 140 may extend along the Y-axis between one or more S/D regions 124 serving as source regions and one or more S/D regions 124 serving as drain regions. While not shown, channel regions are formed between the S/D regions 124 and have at least three surfaces wrapped around by the gate stack 140.

The S/D regions 124 may include a semiconductor material, such as Si or Ge, a III-V compound semiconductor, an II-VI compound semiconductor, or other suitable semiconductor material. Exemplary S/D region 124 may include, but are not limited to, Ge, SiGe, GaAs, AlGaAs, GaAsP, SiP, InAs, AlAs, InP, GaN, InGaAs, InAlAs, GaSb, AIP, GaP, and the like. The S/D regions 124 may include p-type dopants, such as boron; n-type dopants, such as phosphorus or arsenic; and/or other suitable dopants including combinations thereof. The S/D regions 124 may be formed by an epitaxial growth method using CVD, atomic layer deposition (ALD) or molecular beam epitaxy (MBE). The channel regions may include one or more semiconductor materials, such as Si, Ge, GeSn, SiGe, GaAs, InSb, GaP, GaSb, InAlAs, InGaAs, GaSbP, GaAsSb, GaN, or InP. The channel regions may include the same semiconductor material as the substrate 102. In some embodiments, the device layer 200 may include FinFETs, and the channel regions are a plurality of fins disposed below the gate stacks 140. In some embodiments, the device layer 200 may include nanostructure transistors, and the channel regions are surrounded by the gate stacks 140.

The gate stack 140 includes a gate electrode layer 138 disposed over the channel region (or surrounding the channel region for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. The gate stack 140 may further include a gate dielectric layer 136 disposed over the channel region. The gate electrode layer 138 may be disposed over the gate dielectric layer 136. In some embodiments, an interfacial layer (not shown) may be disposed between the channel region 108 and the gate dielectric layer 136, and one or more work function layers (not shown) may be formed between the gate dielectric layer 136 and the gate electrode layer 138. The interfacial dielectric layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for case of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layer 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique. In some embodiments, fin sidewall spacers 123 may be disposed on opposite sides of each S/D region 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

A contact etch stop layer (CESL) 126 is formed on the S/D regions 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D regions 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

S/D contacts 142 may be disposed in the ILD layer 128 and over the S/D regions 124. The S/D contacts 142 may be electrically conductive and include a material having one or more of Ru, Mo, Co, Ni, W, Ti, Ta, Cu, Al, TiN or TaN, and the conductive contact may be formed by any suitable method, such as electro-chemical plating (ECP), CVD, or PVD. A silicide layer 144 may be disposed between the S/D contacts 142 and the S/D regions 124. The silicide layers 144 may be made of a metal or metal alloy silicide, and the metal includes a noble metal, a refractory metal, a rare earth metal, alloys thereof, or combinations thereof.

In integrated circuits, interconnection structures (or interconnect structures) are used to provide signal routing and power supply to semiconductor devices. An integrated circuit chip typically includes a device layer, fabricated during front-end-of-line (FEOL) and middle-end-of-line (MEOL) processes, and a back-end-of-line (BEOL) layer. The device layer may be formed in and/or on the substrate, and the BEOL layer is formed on a front side and/or backside of the device layer. The device layer may include various semiconductor devices, such as transistors, diodes, capacitors, resistors, etc., and may be formed in and/or on the substrate. In some embodiments, the device layer may also include the MEOL structures, such as one or more dielectric layers with conductive structures connected to gates and source/drain features in the device layer. Interconnection structures typically include conductive lines and vias formed in both the device layer and the BEOL layers.

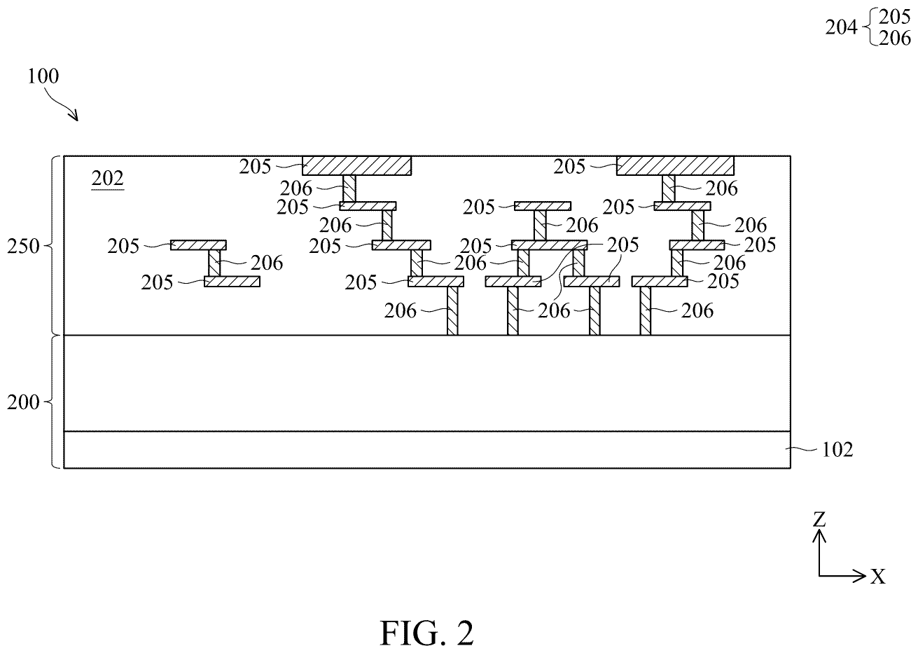

FIG. 2 is a cross-sectional view of an interconnect structure of an intermediate stage of manufacturing the semiconductor device 100 with a detailed structure depicting its interconnect structure, in accordance with some embodiments. The interconnect structure 250 is formed over the device layer 200. The interconnect structure 250 includes various conductive features 204, such as conductive lines 205 and conductive vias 206, formed in a dielectric layer 202. The dielectric layer 202 may be an intermetal dielectric (IMD) layer or an interlayer dielectric (ILD) layer. The dielectric layer 202 may include multiple dielectric layers embedding multiple levels of conductive lines and vias 205, 206. The dielectric layer 202 includes a dielectric material, such as SiOₓ, SiOₓC_{y}H_{z}, or SiOₓC_{y}, where x, y and z are integers or non-integers. In some embodiments, the dielectric layer 202 includes a low-k dielectric material having a k value less than that of silicon oxide. The conductive lines 205 and conductive vias 206 may be made from one or more electrically conductive materials, such as metal, metal alloy, metal nitride, or silicide. The conductive vias 206 and conductive lines 205 are arranged in levels to provide electrical paths to the gate electrode layer 138 (FIG. 1) and S/D contacts 142 (FIG. 1) in the device layer.

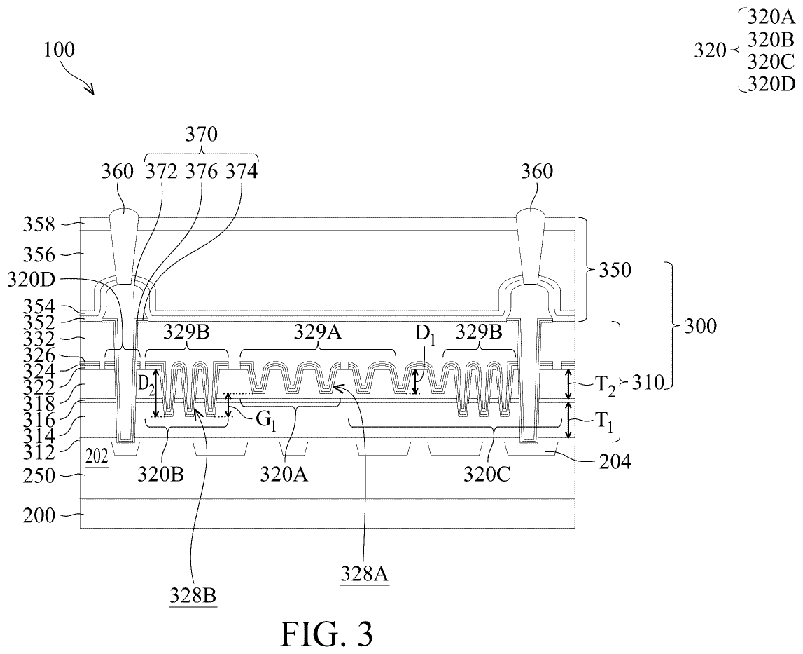

FIG. 3 is a cross-sectional view of an intermediate stage of manufacturing the semiconductor device 100 with a detailed structure depicting its passivation structure, in accordance with some embodiments. In FIG. 3, a passivation structure 300 is formed over the interconnect structure 250. The passivation structure 300 may include a first passivation structure 310 disposed over the interconnect structure 250 and a second passivation structure 350 disposed over the first passivation structure 310. Capacitor structures 320 and/or other passivation devices may be formed in the first passivation structure 310. Bonding structures 360 may be formed in the second passivation structure 350. In some embodiments, conductive through vias 370 extend through the first passivation structure 310 to electrically couple the bonding structures 360 and the conductive features 204 of the interconnect structure 250.

In some embodiments, the first passivation structure 310 includes a first etch stop layer 312 over the dielectric layer 202 of the interconnect structure 250, a first passivation layer 314 over the first etch stop layer 312, a second etch stop layer 316 over the first passivation layer 314, a second passivation layer 318 over the second etch stop layer 316. The first etch stop layer 312 may include a material different from the dielectric layer 202 to have different etch selectivity compared to the dielectric layer 202. In some embodiments, the first etch stop layer 312 is made of an insulating material, such as a carbide, a nitride, a metal oxide, a metal nitride, or a combination thereof. Suitable materials for the first etch stop layer 312 may include, but not limited to silicon carbide, silicon carbon nitride, silicon oxycarbonitride, aluminum nitride, aluminum oxide, titanium oxide, a combination thereof, or the like. The first etch stop layer 312 may be formed by any suitable process, such as CVD, ALD, PVD, PECVD, a combination therefore, or the like. The first etch stop layer 312 has a thickness from about 100 nm to about 200 nm, in accordance with some embodiments. The first etch stop layer 312 may partially or completely resist the etch processes for forming the through holes for containing the conductive through vias 370. As such, an additional etch process with lower etch rate can be implemented to etch through the first etch stop layer for extending the through holes through the first etch stop layer 312, thereby reducing or avoiding overetch that may damage the conductive features 204 of the interconnect structure 250.

The first passivation layer 314 includes a different material from the dielectric layer 202 and the first etch stop layer 312, in accordance with some embodiments. For example, the first passivation layer 314 is a passivation layer that provides, for example moisture seal properties or mechanical robustness, to protect the underlying interconnect structure 250 and device layer 200. The first passivation layer 314 may include a dielectric constant greater than that of the dielectric layer 202 in the interconnect structure 250. In some embodiments, the first passivation layer 314 includes silicon nitride, silicon oxynitride, or a combination thereof. In an embodiment that the dielectric layer 202 is silicon oxide, and the first passivation layer 314 is silicon nitride. The first passivation layer 314 may have a thickness Ti of about 150 nm to about 500 nm.

The second etch stop layer 316 may include a material different form the first passivation layer 314 to have different etch selectivity compared to the first passivation layer 314. For example, the second etch stop layer 316 may be or include a high-resistance material, such as silicon carbon nitride, silicon carbide, silicon oxycarbonitride, undoped silicon, undoped germanium, undoped silicon germanium, silicon nitride, hafnium oxide, zirconium oxide, or a stacked structure including oxide-nitride-oxide layers (e.g., SiO—SiN—SiO). The second etch stop layer 316 has a thickness greater than the first etch stop layer 312 and less than that of the first passivation layer 314. For example, the second etch stop layer 316 may have a thickness of about 30 nm to about 80 nm.

The second passivation layer 318 includes a different material from the dielectric layer 202 and the second etch stop layer 316, in accordance with some embodiments. For example, the second passivation layer 318 is a passivation layer that provides, for example moisture seal properties or mechanical robustness, to protect the underlying interconnect structure 250 and device layer 200. The second passivation layer 318 may be or include a similar material as those of the first passivation layer 314. For example, the second passivation layer 318 includes silicon nitride, silicon oxynitride, or a combination thereof. The second passivation layer 318 may have a thickness of about 150 μm to about 500 μm. In some embodiments, the second passivation layer 318 has a substantially same thickness as the first passivation layer 314, although different thicknesses may be implemented for the first and second passivation layers 314 and 318.

The capacitor structures 320 are formed over the second passivation layer 318. The capacitor structures 320 extend into the first passivation layer 314, the second etch stop layer 316, and the second passivation layer 318 to increase surface areas, in accordance with some embodiments. The capacitor structures 320 may be a metal-insulator-metal (MIM) structure. For example, the capacitor structures 320 may each include a first conductive layer 322, an insulating layer 324 over the first conductive layer 322, and a second conductive layer 326 over the insulating layer 324. Although three layers are illustrated in FIG. 3, the capacitor structures 320 may include more layers.

In an embodiment, the first conductive layer 322 includes one or more layers of Cu, Al, W, Co, Ti, Ta, TiN, TaN, or an alloy thereof. In some embodiments, the thickness of the first conductive layer 322 is in a range from about 10 nm to about 100 nm, depending on the design and/or process requirements. The insulating layer 324 is formed over the first conductive layer 322 and the first passivation layer 314. In some embodiments, the insulating layer 324 includes one or more high-k dielectric layers having a dielectric constant greater than that of silicon oxide. In some embodiments, the first insulating layer 120 includes one or more layers of a metal oxide or a silicate of Hf, Al, Zr, combinations thereof, and multi-layers thereof. In certain embodiments, hafnium oxide is used. Other suitable materials include La, Mg, Ba, Ti, Pb, Zr, in the form of metal oxides, metal alloy oxides, and combinations thereof. Exemplary materials include MgO, BaTIO, BaSrTiO, PbTIO, PbZrTiyO, AlO, LaO, TaO, YO, HfO, ZrO, HfSiON, YGeO, YSIO and LaAIO, a combination therefore, or the like. In some embodiments, the insulating layer 324 has a thickness in a range from about 1 nm to about 10 nm, and in a range from about 2 nm to about 5 nm in other embodiments, depending on design and/or process requirements. The second conductive layer 326 may include or be the same material as the first conductive layer 322. In some embodiments, seams or air gaps may be formed in the capacitor structures 320, being sealed by second conductive layer 326 or the insulating layer 324. In some embodiments, at least a portion of the first conductive layer 322 over an upper surface of the second passivation layer 318 has a curved top surface. At least a portion of the insulating layer 324 over an upper surface of the second passivation layer 318 may have a curved top surface. At least a portion of the second conductive layer 326 over an upper surface of the second passivation layer 318 may have a curved top surface.

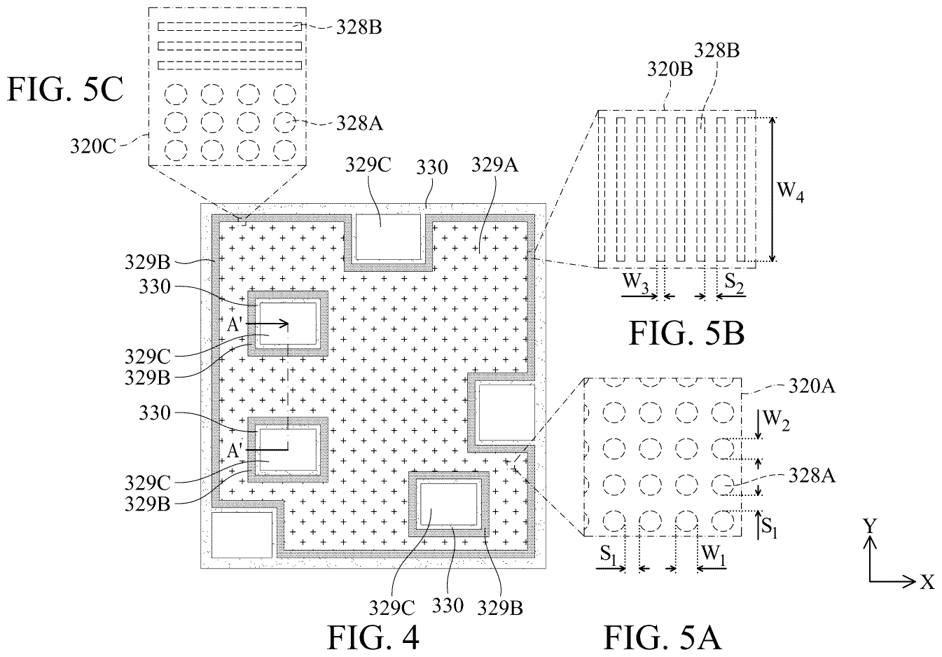

A plurality of holes 328A and trenches 328B are formed in the second passivation layer 318, in accordance with some embodiments. The holes 328A and the trenches 328B may extend from an upper surface of the second passivation layer 318 and into the second passivation layer 318. For example, referring to FIGS. 4 and 5A-5C, the holes 328A may be arranged in a matrix manner in hole regions 329A. The holes 328A may each have a circular shape or a circular-like shape in the plan view. For example, at least one of the holes has first width W₁ in a first direction (e.g., X-direction in FIG. 4) and a second width W₂ in a second direction (e.g., Y-direction in FIG. 4) perpendicular to the first direction. The trenches 328B may have a longitudinal axis along the first direction and be repetitively arranged in the second direction and/or have a longitudinal axis along a second direction and be repetitively arranged in the first direction. For example, as illustrated in FIG. 4, at least one of the trenches 328B has third width W₃ in the first direction and a fourth width W₄ in the second direction (e.g., Y-direction in FIG. 4), and the fourth width W₄ is greater than the third width W₃. In some embodiments, a difference between the first width W₁ and the second width W₂ is smaller than a difference between the third width W₃ and the fourth width W₄, and a second spacing S₂ between neighboring trenches 328B of the trench-type capacitors 320B is smaller than a first spacing S₁ of the hole-type capacitors 320A.

Referring back to FIG. 3, the capacitor structures 320 may include portions extending into in the holes 328A and trenches 328B. For example, the capacitor structures 320 may include one or more hole-type capacitors 320A, one or more trench-type capacitors 320B, one or more hybrid-type capacitors 320C, and one or more dummy MIM structures 320D. The hole-type capacitor 320A may include first conductive layer 322, the insulating layer 324, the second conductive layer 326 disposed over the upper surface of the insulating layer 324 and extending into the holes 328A. The trench-type capacitor 320B may include the first conductive layer 322, the insulating layer 324, the second conductive layer 326 disposed over the upper surface of the insulating layer 324 and extending into the trenches 328B. The hybrid-type capacitors 320C may include the first conductive layer 322, the insulating layer 324, the second conductive layer 326 disposed over the upper surface of the insulating layer 324 and extending into the holes 328A and the trenches 328B. The dummy MIM structure 320D may be disposed over the second passivation layer 318. The dummy MIM structure 320D may be electrically isolated from other capacitors in the capacitor structures 320.

As will be discussed below, the holes 328A for containing the hole-type capacitors 320A and the trenches 328B for containing the trench-type capacitors 320B may be formed in a same process, where the etch rate in forming the trenches 328B would be greater than the etch rate in forming the holes 328A due to pattern differences. The trenches 328B may be etched deeper than the holes 328A after the etch processes. For example, the holes 328A may have a depth D₁ ranging from about 200 to about 400 nm, such as from about 100 nm to about 300 nm, although deeper or shallower holes may be used. The trenches 328B may have a depth D₂ ranging from about 500 μm to about 850 nm, such as about 600 nm to about 700 nm, although deeper or shallower trenches may be used. The trenches 328B and the holes 328A may have a vertical gap G₁ of about 100 nm to about 300 nm, which is about 0.5 times to about 1.5 times of depth D₁ of the holes 328A.

In some embodiments, the trenches 328B have a bottom below the second etch stop layer 316, and the holes 328A have a bottom above the second etch stop layer 316. Thus, the trench-type capacitors 320B have a deeper depth than the hole-type capacitors 320A. In some embodiments, after the etch process, the trench-type capacitors 320B penetrate through the second etch stop layer 316 while the hole-type capacitors 320A are above the second etch stop layer 316. As illustrated in FIG. 3, the first conductive layer 322 in the hole-type capacitors 320A may have a distance from the second etch stop layer 316, and the first conductive layer 322 in the trench-type capacitors 320B may be in contact with the second etch stop layer 316.

The first passivation structure 310 further includes a filling layer 332 over the capacitor structures 320, in accordance with some embodiment. The filling layer 332 may extend into and fill the remaining space of the holes 328A and/or the trenches 328B. The filling layer 332 also acts as an isolation layer electrically isolating one of the capacitor structures 320 from each other. The filling layer 332 may have a similar material as the first passivation layer 314 or the second passivation layer 318. In an embodiment, the filling layer 332 has a planar upper surface.

Conductive through vias 370 are formed in the first passivation layer 314, the second etch stop layer 316, and the second passivation layer 318, in accordance with some embodiments. The conductive through vias 370 may extend through the first etch stop layer 312 to be electrically coupled to the underlying conductive features 204 of the interconnect structure 250. The conductive through vias 370 may include a low-resistivity main conductive material 372, such as Cu, W, Ru, Al, Au, Ag, or a combination thereof. The conductive through vias 370 may also include a barrier layer 374 and/or a seed layer 376 between the main conductive material 372 and layers neighboring the conductive through vias 370. The barrier layer 374 may include a metal such as Ti, Ta, Ru, or a metal nitride such as TiN, TaN, or a combination thereof. The barrier layer 374 may have a thickness ranging from about 1 nm to about 10 nm. If the thickness of the barrier layer 374 is less than about 1 nm, the barrier layer 374 may not be sufficient to prevent diffusion of main conductive material 372. The seed layer 376 may include Cu, Ti, or a composite structure containing Cu and Ti layers.

One conductive through via 370 may also penetrate through one of the capacitor structure 320, such as penetrating through the second conductive layer 326, the insulating layer 324, and the first conductive layer 322. According to the design requirements, the conductive through via 370 may penetrate through the hole-type capacitor 320A, the trench-type capacitor 320B, or the hybrid-type capacitor 320C to be electrically coupled to the hole-type capacitor 320A, the trench-type capacitor 320B, or the hybrid-type capacitor 320C. Alternatively, when the conductive through via 370 are designed to not be electrically coupled to active capacitor structure 320 (e.g., 320A, 320B, or 320C), the conductive through vias 370 may penetrate through the dummy MIM structure 320D.

FIG. 4 is a scheme for illustrating regions for arranging capacitor structures in a unit area of the semiconductor device 100 in a plan view, in accordance with some embodiments. FIGS. 5A, 5B and 5C illustrate enlarged views of a hole-type capacitor 320A, a trench-type capacitor 320B, and a hybrid-type capacitor 320C, respectively, in the regions illustrated in FIG. 4, in accordance with some embodiments. FIG. 3 is a corresponding cross-sectional view along the section A-A′ as illustrated in FIG. 4, in accordance with some embodiments. The semiconductor device 100 may include hole regions 329A where the holes 328A are formed therein and for arranging the hole-type capacitors 320A. The semiconductor device 100 may also include trench regions 329B where the trenches 328B are formed therein and for arranging the trench-type capacitors 320B. The semiconductor device 100 may also include via regions 329C for arranging the conductive through vias 370 therein and isolation regions 330 which may be filled with the filling layer 332.

It is found that the hole-type capacitors 320A may generate less stress than the trench-type capacitors 320B. Thus, in the semiconductor device, the hole regions 329A may occupy a major portion of the unit area of the semiconductor device 100, and the trench regions 329B may be located at or adjacent to the edges of the hole regions 329A. For example, in the semiconductor device 100 as illustrated in FIG. 4, the hole regions 329A may have a footprint larger than the footprint of trench regions 329B to reduce the stress of the semiconductor device 100, thereby reducing or preventing film cracking or delamination. On the other hand, the trenches 328B of the trench-type capacitors 320B have smaller width and spacing than that of the holes 328A of the hole-type capacitors 320A. Thus, the trench regions 329B for the trench-type capacitors 320B may be arranged at the edges of the hole regions 329A, such as disposed at regions near the via regions 329C or the edges of the unit area of the semiconductor device 100. In some embodiments, as illustrated in FIG. 4, one trench region 329B is disposed interposed between the via region 329C and the hole region 329A. In some embodiments, a via region 329C is surrounded by a trench region 329B, and/or further surrounded by the hole region 329A. In some embodiments, the via region 329C is surrounded by collectively the trench region 329B and the isolation region 330.

Because the presence of the trench-type capacitors 320B (or hybrid-type capacitors 320C) can improve the pattern density of the capacitor structures 320. Thus, capacitor density and routing design flexibility of the capacitor structures 320 may be improved. In addition, the trench-type capacitors 320B may only generate limited or ignorable stress that may not result in film cracking or delamination problems when its footprint in a given area is limited.

Referring back to FIG. 3, the second passivation structure 350 is formed over the first passivation structure 310, in accordance with some embodiments. The second passivation structure 350 may include a third passivation layer 352 formed over the filling layer 332, a fourth passivation layer 354 formed over the third passivation layer 352, and a dielectric layer 356 formed over the fourth passivation layer 354. In an embodiment, the third passivation layer 352 includes or is silicon nitride, silicon oxynitride, silicon carbide, silicon oxycarbonitride, a combination thereof, or the like. The fourth passivation layer 354 includes a material different from the third passivation layer 352, such as silicon oxide or glass, including silicate glass, borosilicate glass (BSG), phosphosilicate glass (PSG), borophosphosilicate glass (BPSG), a combination thereof, or the like. The dielectric layer 356 includes silicon oxide, silicate glass, a molding compound, or an organic material such as polybenzoxazoles (PBO), polyimide (PI), benzocyclobutene (BCB), other suitable organic polymers, or a combination thereof. The third passivation layer 352 and the fourth passivation layer 354 may be conformal layers. The dielectric layer 356 has a thickness greater than the third passivation layer 352 and the fourth passivation layer 354 and has a planar upper surface. In some embodiments, one of the third passivation layer 352 and the fourth passivation layer 354 may be omitted for saving cost.

In some embodiments, the conductive through vias 370 protrude over the first passivation structure 310 and extend into the second passivation structure 350, although the conductive through vias 370 may have a top surface level with the top surface of the second passivation layer 318. In embodiments that the conductive through vias 370 extend into the second passivation structure 350, third passivation layer 352 and the fourth passivation layer 354 are conformally lying on the conductive through vias 370. In some embodiments, the protrusions of the conductive through vias 370 are conductive lines and thus the conductive through vias 370 can serve as a redistribution layer.

In some embodiments, the bonding structures 360 are formed in the dielectric layer 356. The bonding structures 360 may further penetrate through the fourth passivation layer 354 and the third passivation layer 352 to be physically and/or electrically coupled to the conductive through vias 370. The bonding structures 360 may include Cu or other materials suitable for bonding (e.g., Ni, Au, Ag, Pd, Al, Sn). In some embodiments, the bonding structures 360 may also include barrier layer and/seed layer similar to the conductive through vias 370. Depending on the bonding requirements, the bonding structures 360 may be bump that protrudes over the dielectric layer 356 or have a top surface level with the top surface of the dielectric layer 356. In an embodiments, another dielectric layer (e.g., silicon oxide) may be additionally formed over the dielectric layer 356 for providing bonding functions, and the bonding structures 360 may protrude over or have a top surface level with the bonding layer 358.

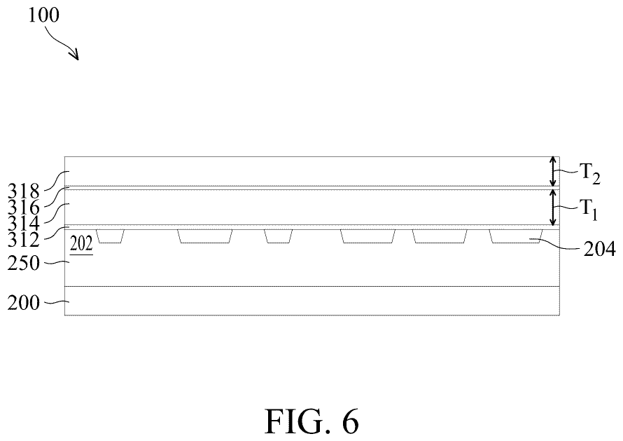

FIGS. 6 to 12 illustrate cross-sectional views at intermediate stages in the manufacturing the semiconductor device 100, in accordance with some embodiments. In FIG. 6, after the device layer 200 and the interconnect structure 250 are formed over the substrate 102, a first etch stop layer 312 and the first passivation layer 314, the second etch stop layer 316, and the second passivation layer 318 are formed over the dielectric layer 202 and conductive features 204 sequentially. The first etch stop layer 312, the first passivation layer 314, the second etch stop layer 316, and the second passivation layer 318 may each be formed by a suitable deposition process, such as CVD, ALD, PVD, PECVD, a combination thereof, or the like. In some embodiments, the first etch stop layer 312, the first passivation layer 314, the second etch stop layer 316, and the second passivation layer 318 may be formed in a same deposition machine or in a same chamber of the deposition machine to increase the production throughput, since transport time periods between different chambers or deposition machines can be saved.

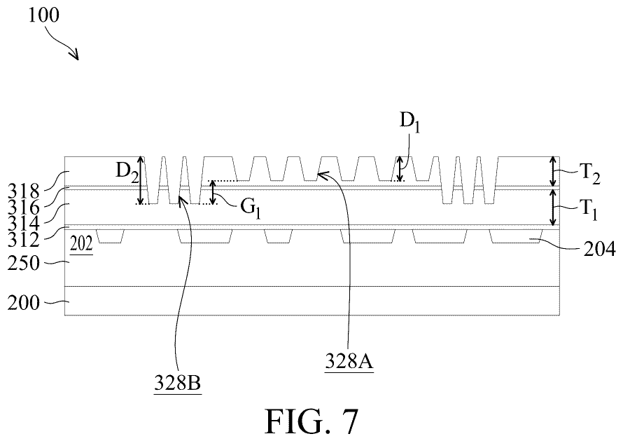

In FIG. 7, an anisotropic etch process may be formed to form the holes 328A for containing the hole-type capacitors 320A and the trenches 328B for containing the trench-type capacitors 320B in second passivation layer 318 and its underlying layers, in accordance with some embodiments. In an embodiment, a patterned mask is formed over the second passivation layer 318. The patterned mask may be a photoresist material, a hard mask (e.g., silicon oxide, TiN, TiO, or the like), or a combination thereof. An etch process may then be performed to transfer the pattern of the patterned mask to the underlying layers. The etch process may be an anisotropic etch process such as reactive ion etching (RIE) or neutral beam etching (NBE). For example, the etch process may include chemical including HBr, NF₃, O₂, SF₆, or combination thereof and physical ion bombardment.

Although the holes 328A and the trenches 328B are formed in a same etch process, it is found the etch rate of forming the trenches 328B is faster than the etch rate of forming the holes 328A. In an embodiment, the etch rate of forming the trenches 328B is up to about 3 times faster than the etch rate of forming the holes 328A. Thus, when the holes 328A are etched to reach the desired depths, the trenches 328B may penetrate through the second passivation layer 318, the second etch stop layer 316, and the first passivation layer 314, thereby causing unwanted shorts between the trench-type capacitors 320B and the conductive features 204 of the interconnect structure 250. The presence of the second etch stop layer 316 may effectively reduce the etch rate of forming the trenches 328B, thereby preventing from or reducing frequencies the trenches 328B penetrating through first passivation layer 314 and the first etch stop layer 312.

As illustrated in FIG. 7, the trenches 328B extend through the second etch stop layer 316 and partially into the first passivation layer 314, in accordance with some embodiments. In other embodiments, the trenches 328B land on the second etch stop layer 316 without extending through the second etch stop layer 316. The presence of second etch stop layer 316 may also reduce the gap G₁ between the bottom of the holes 328A and the trenches 328B. Thus, capacitance densities of the capacitor structures 320 can be increased in given thicknesses of the second passivation layer 318 and the first passivation layer 314 since hole-type capacitors 320A which occupy a relatively large area can be designed to have deeper depths due to the reduced gap G₁. In some embodiments, during the etch process, when the trenches 328B penetrate through the second etch stop layer 316, the holes 328A may still have a distance from the second etch stop layer 316. The patterned mask may be removed by, for example, as ashing process or an etch process, after the holes 328A and the trenches 328B are formed.

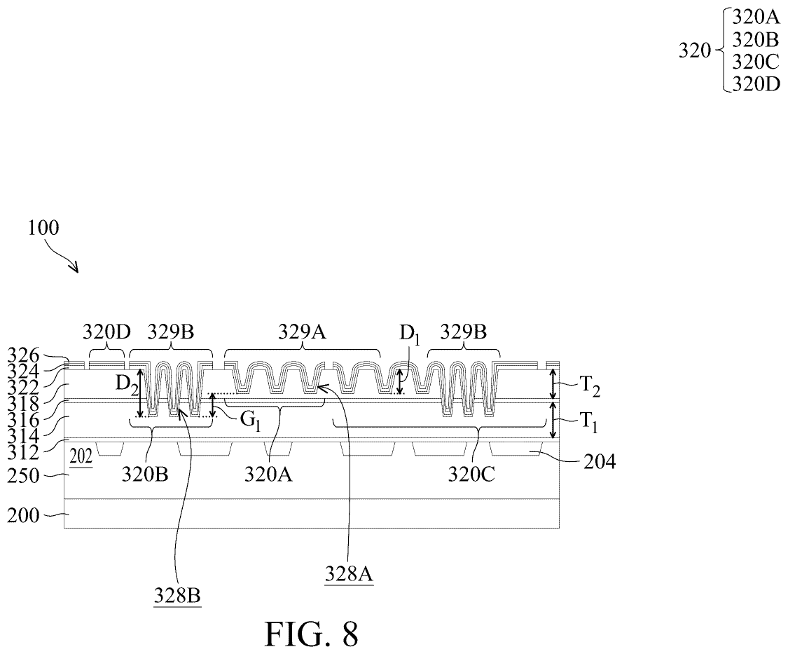

In FIG. 8, the first conductive layer 322, the insulating layer 324, and the second conductive layer 326 are formed in the trenches 328B, holes 328A and the top surface of the second passivation layer 318, in accordance with some embodiments. In detail, the first conductive layer 322 is conformally formed in the holes 328A and the trenches 328B over the upper surface of the second passivation layer 318. The first conductive layer 322 may be formed by PVD, CVD, or ALD. The insulating layer 324 is conformally formed over the first conductive layer 322. In some embodiments, the insulating layer 324 is formed by CVD or ALD. Next, the second conductive layer 326 is conformally formed over the insulating layer 324. The second conductive layer 326 may be formed by PVD, CVD, or ALD. In some embodiments, because the trenches 328B may have a smaller width, the trenches 328B may be sealed by the second conductive layer 326 or the insulating layer 324 while the holes 328A are not. Thus, scam or air gaps are formed in the trenches 328B but not in the holes 328A. In some embodiments, the holes 328A may be also sealed, such as by the second conductive layer 326 or when more layers are used for the capacitor structures 320.

After the first conductive layer 322, the insulating layer 324, and the second conductive layer 326 are formed, an anisotropic etch process may be performed to etch the first conductive layer 322, the insulating layer 324, and the second conductive layer 326 so as to define boundaries of each one of the capacitor structures 320. Although a single etch process may be used to define the boundaries of the capacitor structures 320 as illustrated above, the pattern of each layer 322, 324, 326 of the capacitor structures 320 may be defined individually, such as each layer 322, 324, 326 being individually patterned by one ore more etch processes right after their depositions are before the formation of a next layer.

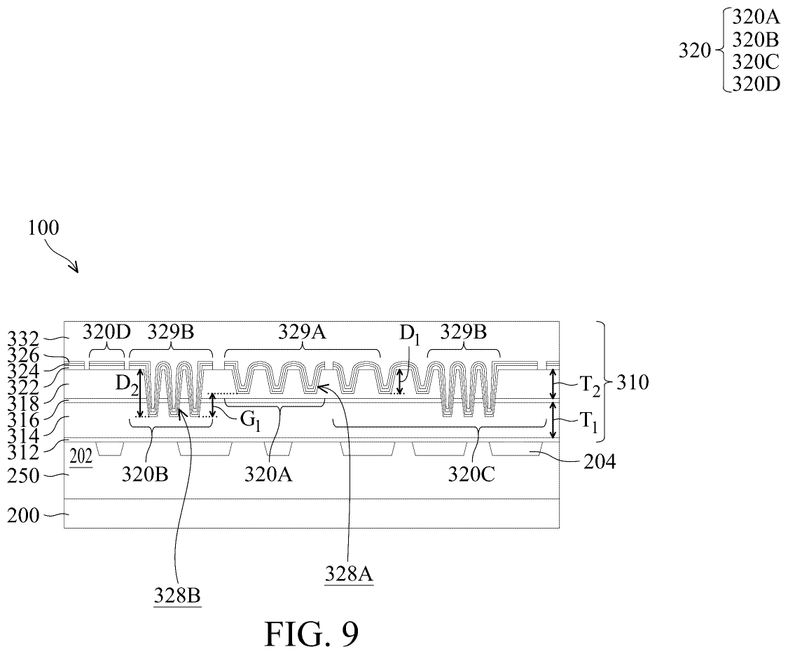

In FIG. 9, after the capacitor structures 320 are formed, a filling layer 332 is formed to cover the capacitor structures 320, in accordance with some embodiments. In embodiments that the trenches 328B and/or holes 328A are not sealed, the filling layer 332 may extend into the trenches 328B and/or holes 328A to fill in the remaining space of the trenches 328B and/or holes 328A. The filling layer 332 may be formed by a suitable deposition process, such as CVD, PECVD, LPCVD, or the like, and a planarized process such as chemical mechanic polish (CMP) may be performed to planarize the upper surface of the filling layer 332.

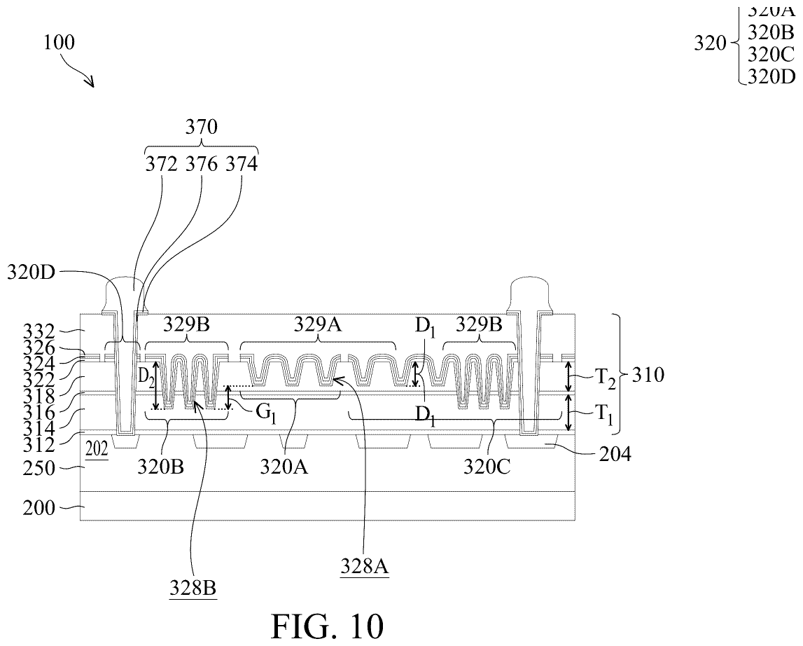

In FIG. 10, the conductive through vias 370 are formed in the first etch stop layer 312, the first passivation layer 314, the second etch stop layer 316, the second passivation layer 318, the capacitor structures 320, and the filling layer 332, in accordance with some embodiments. The conductive through vias 370 may be electrically coupled to the conductive features 204 of the interconnect structure. The conductive through vias 370 may be formed by one or more etch process and depositing layers in the openings. The etch processes may include an anisotropic process such as RIE or NBE. In some embodiments, a mask such as a hard mask layer may be disposed over the filling layer 332 prior to perform the etch process. The hard mask may include silicon oxide, titanium nitride, aluminum oxide, titanium oxide, or a combination thereof.

After the openings for the conductive through vias 370 are formed, the barrier layer 374, the seed layer 376, and the main conductive material 372 are formed in the openings subsequently. The barrier layer 374 and the seed layer 376 are be conformally deposited in the openings and over the upper surface of the filling layer 332, such as by ALD, CVD, or PVD. Next, a photoresist layer is formed over the barrier layer 374 or the seed layer 376 and patterned to expose the portions of the seed layer 376 in the openings and its adjacent portions. In some embodiments, a plating (e.g., electroplating or electroless plating) or other suitable deposition process is performed to formed the main conductive material 372 over the exposed portions of the seed layer 376. The as-deposited conductive through vias 370 may include protrusions over the upper surface of the filling layer 332. After the conductive through vias 370 are formed, the photoresist layer is removed by a suitable process, such as by a wet strip or ashing process, and the portions of seed layer 376 and barrier layer 374 are also removed by suitable wet etch processes. As illustrated in FIG. 3, the protrusions of conductive through vias 370 may remain and be covered by the second passivation structure 350. Alternatively, the protrusions of the conductive through vias 370 may be removed by a planarized process, such as CMP, depending on the design requirements of the bonding structures 360.

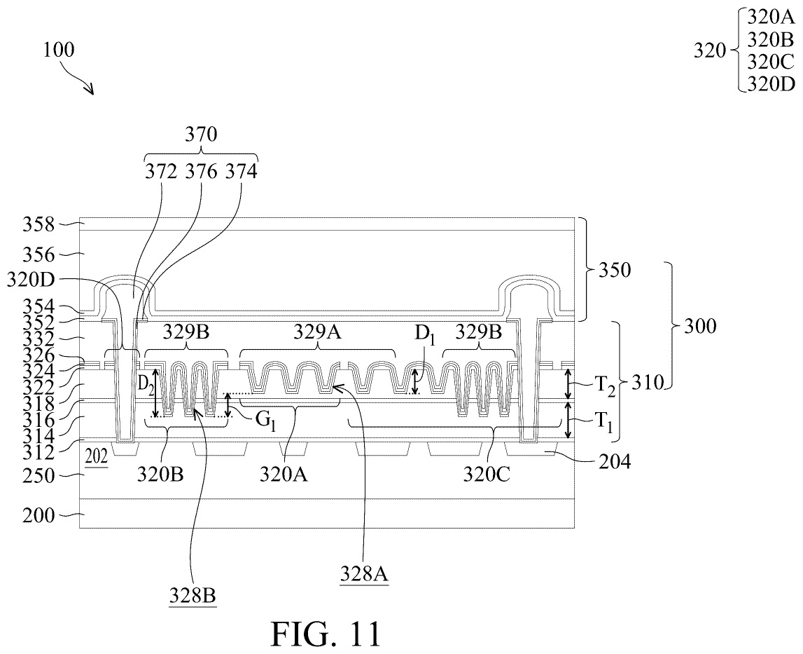

In FIG. 11, the second passivation structure 350 is formed over the first passivation structure 310 and the conductive through vias 370, in accordance with some embodiments. The formation of the second passivation structure 350 may include forming the third passivation layer 352 over the upper surfaces of the filling layer 332 and the conductive through vias 370 and forming the optional fourth passivation layer 354 over the third passivation layer 352. The third passivation layer 352 and the fourth passivation layer 354 may be conformally deposited, such as by CVD, PVD, ALD, or a combination thereof. Next, the dielectric layer 356 is formed over the third passivation layer 352 or the fourth passivation layer 354 (if exist). The dielectric layer 356 may be formed by suitable deposition processes, such as, CVD, PECVD, LPCVD, MOCVD, spin coating, a combination thereof, or the like. A planarized process such as CMP or mechanical grinding may be performed after the dielectric layer 356 are deposited. In some embodiments that the bonding layer 358 is needed, the bonding layer 358 is deposited over the upper surface of the dielectric layer 356, such as by CVD, PECVD, LPCVD, ALD, PVD, or the like.

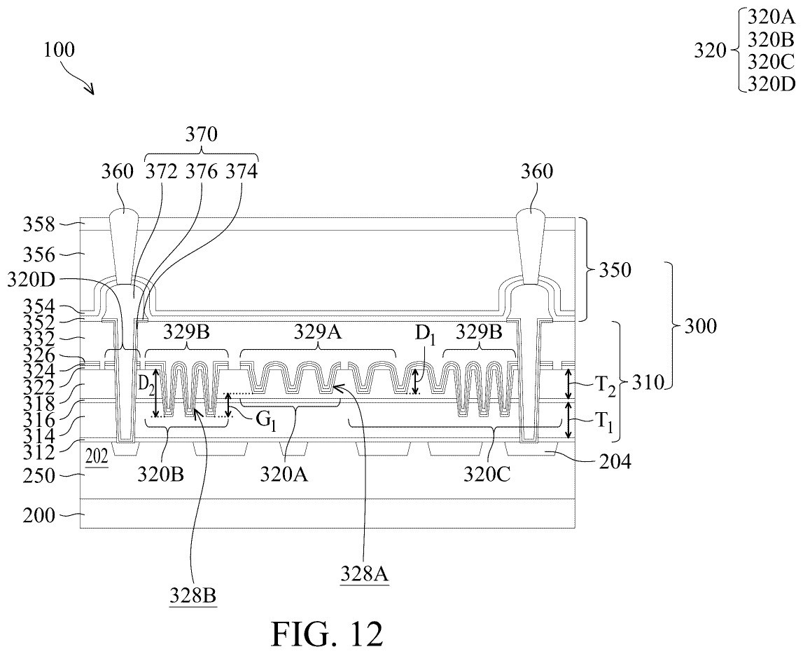

In FIG. 12, bonding structures 360 are formed in the dielectric layer 356 (and the bonding layer 358, if exists), in accordance with some embodiments. The formation of the bonding structures 360 may include forming openings penetrating the dielectric layer 356, the fourth passivation layer 354, and the third passivation layer 352 to expose the conductive through vias 370 by one or more etch processes and then disposing or depositing suitable conductive materials in the openings. In some embodiments, a planarization process is performed to planarize the bonding structures 360 to make the upper surface of the bonding structures 360 have an upper surface level with the upper surface of the dielectric layer 356 or the upper surface of the bonding layer 358, which may facilitate a direct bonding process.

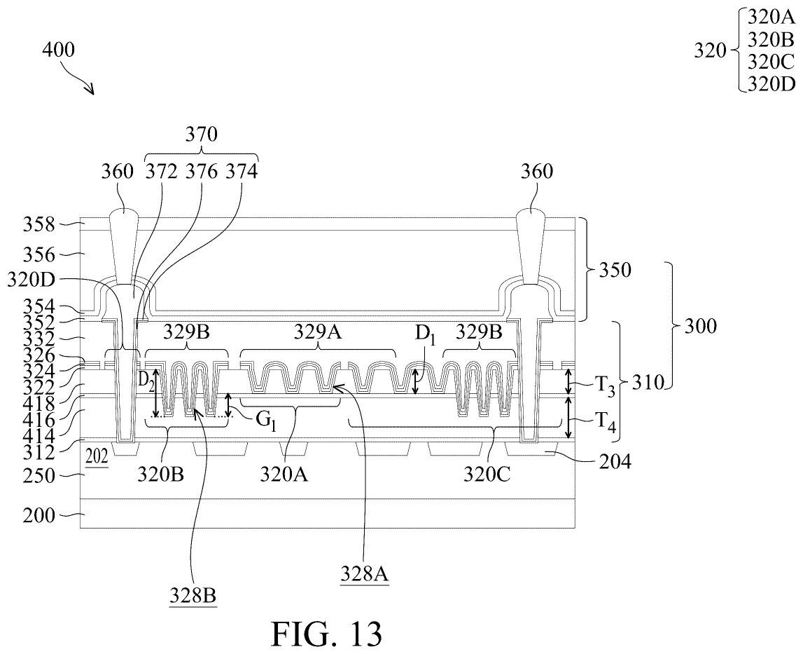

FIG. 13 illustrates a cross-sectional view of a semiconductor device 400, in accordance with some embodiments. The semiconductor device 400 is similar to the semiconductor device 100, wherein same reference numeral represents same elements. In the semiconductor device 400, the second etch stop layer 416 may serve as the etch stop for both holes 328A and the trenches 328B. In FIG. 13, the second passivation layer 418 may have a thickness T₃ substantially equal to the desired depth D₁ of the hole-type capacitors 320A although the hole-type capacitors 320A may be greater or shallower than the thickness T₃ in the manufacturing. The first passivation layer 414 may have a thickness T₄ greater than the thickness T₃ of the second passivation layer 418 to achieve the goal that the thickness T₃ substantially equal to the desired depth D₁ of the hole-type capacitors 320A. In some embodiments, the thickness T₄ of the first passivation layer 414 is at least two times greater than the thickness T₃ of the second passivation layer 418. Because the second etch stop layer 416 can effectively reduce the etch rate of forming the trenches 328B, and sufficient thick first passivation layer 414 is provided, the trenches 328B may not penetrate through the first passivation layer 414. In some embodiments, the first passivation layer 414, the second etch stop layer 416, and the second passivation layer 418 have the same material as the first passivation layer 314, the second etch stop layer 316, and the second passivation layer 318, respectively, and may be formed by similar methods.

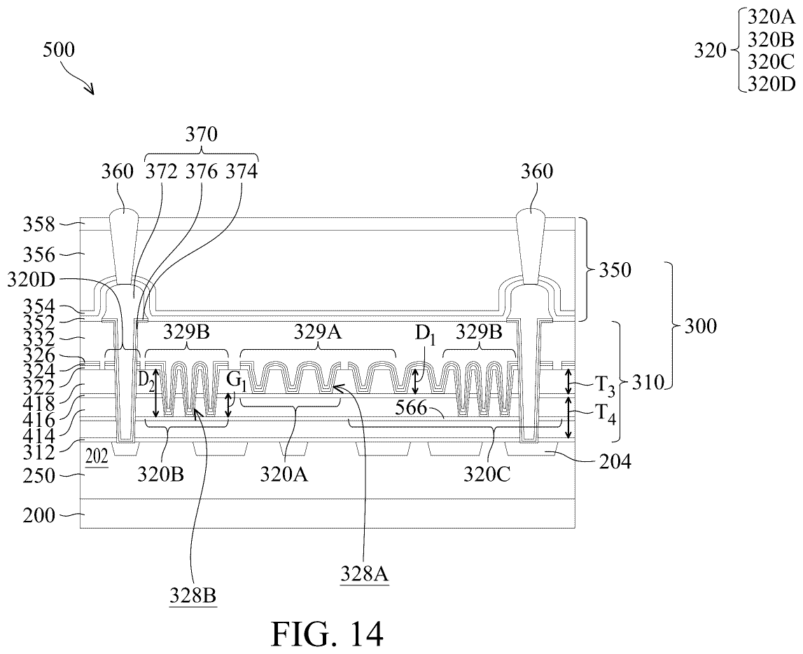

FIG. 14 illustrates a cross-sectional view of a semiconductor device 500, in accordance with some embodiments. The semiconductor device 500 is similar to the semiconductor device 400, wherein same reference numeral represents same elements. In the semiconductor device 500, the second etch stop layer 416 may serve as the etch stop for reducing etch rates of forming the holes 328A and the trenches 328B. In some embodiments, a third etch stop layer 566 is disposed in the first passivation layer 314 to provide additional protection for preventing the trenches 328B from penetrate through the first passivation layer 314. The third etch stop layer 566 may successfully stop the etching for trenches 328B and allows the trenches 328B to land on the third etch stop layer 566. Alternatively, the trenches 328B (or the trench-type capacitors 320B) may still penetrate through the third etch stop layer 566 but have a distance from the first etch stop layer 312. The third etch stop layer 566 may be or include the same material and thickness as the second etch stop layer 416 and may be formed by similar methods.

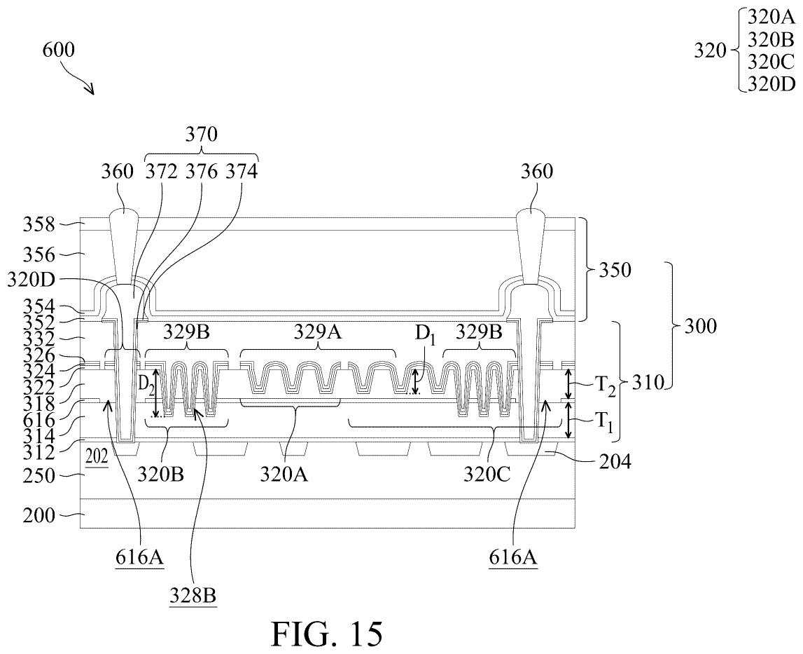

FIG. 15 illustrates a cross-sectional view of a semiconductor device 600, in accordance with some embodiments. The semiconductor device 600 is similar to the semiconductor device 100, 400 or 500, wherein same reference numeral represents same elements. In the semiconductor device 600, the second etch stop layer 616 may have openings 616A to allow the conductive through vias 370 to penetrate through. The openings 616A of the second etch stop layer are filled with the second passivation layer 318. Thus, the second etch stop layer 616 may be separated from the conductive through vias 370 by the second passivation layer 318. The second etch stop layer 616 may include a material different from the first passivation layer 314 to have different etch selectivity compared to the first passivation layer 314. For example, the second etch stop layer 616 may include or be a high-resistance material, such as silicon carbon nitride, silicon carbide, silicon oxycarbonitride, undoped silicon, undoped germanium, undoped silicon germanium, silicon nitride, hafnium oxide, zirconium oxide, or a stacked structure including oxide-nitride-oxide layers (e.g., SiO—SiN—SiO). The second etch stop layer 616 may be formed by methods similar to those of the second etch stop layer 316.

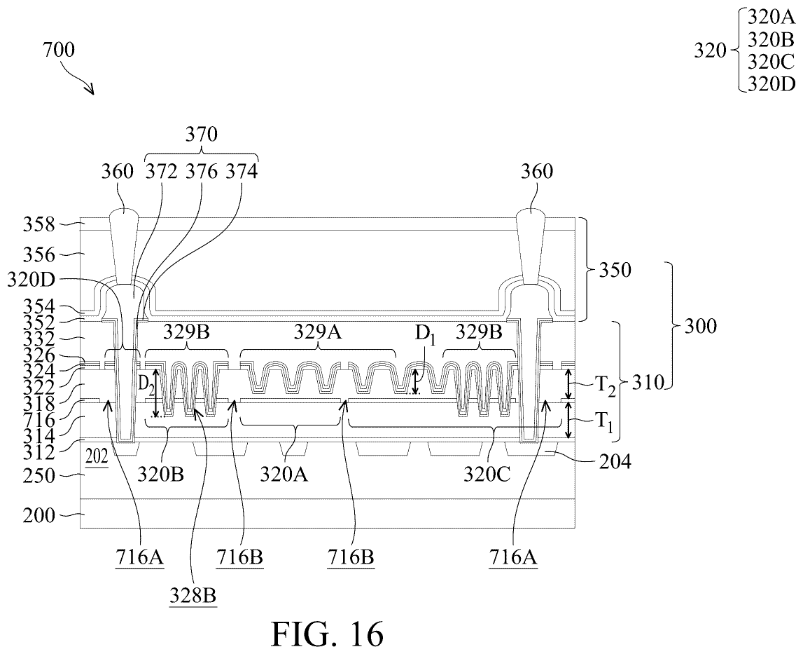

FIG. 16 illustrates a cross-sectional view of a semiconductor device 700, in accordance with some embodiments. The semiconductor device 700 is similar to the semiconductor device 100, 400, 500, or 600, wherein same reference numeral represents same elements. In the semiconductor device 700, the second etch stop layer 716 is or includes a low-resistance material such as a metal material or a metal nitride material. In some embodiments, the low-resistance material includes TiN, TaN, W, Ta, Ti, or a combination thereof. The second etch stop layer 716 may have openings 716A to allow the conductive through vias 370 to penetrate through. The second passivation layer 318 may fill in the openings 716A. Thus, the second etch stop layer 716 may be separated from the conductive through vias 370 by the second passivation layer 318. In addition, except for the openings 716A, the second etch stop layer 716 includes a same pattern to the first conductive layer 322 that is used to define the boundaries of the capacitor structures 320. Because the second etch stop layer 716 is in contact with the first conductive layers 322 of the capacitor structure 320, having a pattern corresponding to the first conductive layer 322 may prevent unwanted short among the capacitor structures 320. For example, as illustrated in FIG. 14, the second etch stop layer 716 does not only include the openings 716A to be electrically isolated from the conductive through vias 370 but also include openings 716B to electrically isolate the capacitor structures 320 from each other (e.g., electrically isolate the hole-type capacitor 320A and the trench-type capacitor 320B as illustrated in FIG. 14), where the openings 716A and the openings 716B are filled with the second passivation layer 318.

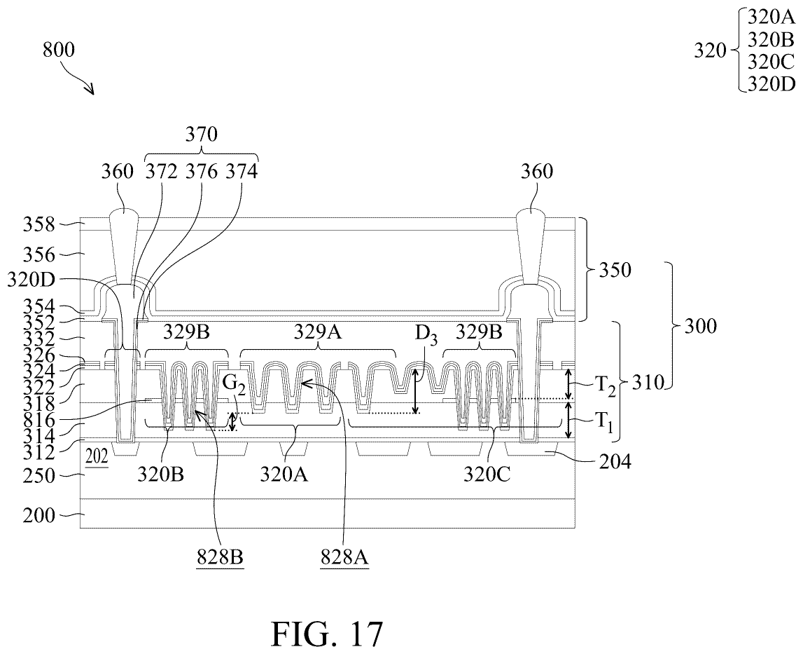

FIG. 17 illustrates a cross-sectional view of a semiconductor device 800, in accordance with some embodiments. The semiconductor device 800 is similar to the semiconductor device 100, 400, 500, 600, or 700, wherein same reference numeral represents same elements. In the semiconductor device 800, the second etch stop layer 816 is only below the trench-type capacitors 320B. That is, the second etch stop layer 816 may only serve function as the etch stop layer for forming the trenches 328B. As such, in some embodiments that the holes 328A are etched to a deeper depth D₃ (e.g., about 400 nm to about 600 nm) that is below the second etch stop layer 816, the etch rate for forming the holes 328A would be affected by the second etch stop layer 816, thereby reducing the gap G₂ between the hole-type capacitors 320A and the trench-type capacitors 320B. The gap G₂ may be in a range between about 50 nm to about 150 nm, which is less than the depth D₃ of the holes 828A. In some embodiments, the second etch stop layer 816 includes high-resistance material, such as silicon carbon nitride, silicon carbide, silicon oxycarbonitride, undoped silicon, undoped germanium, undoped silicon germanium, silicon nitride, hafnium oxide, zirconium oxide, or a stacked structure including oxide-nitride-oxide layers (e.g., SiO—SiN—SiO). Alternatively, the second etch stop layer 816 is or includes a low-resistance material such as a metal material or a metal nitride material. The low-resistance material may include TiN, TaN, W, Ta, Ti, or a combination thereof.

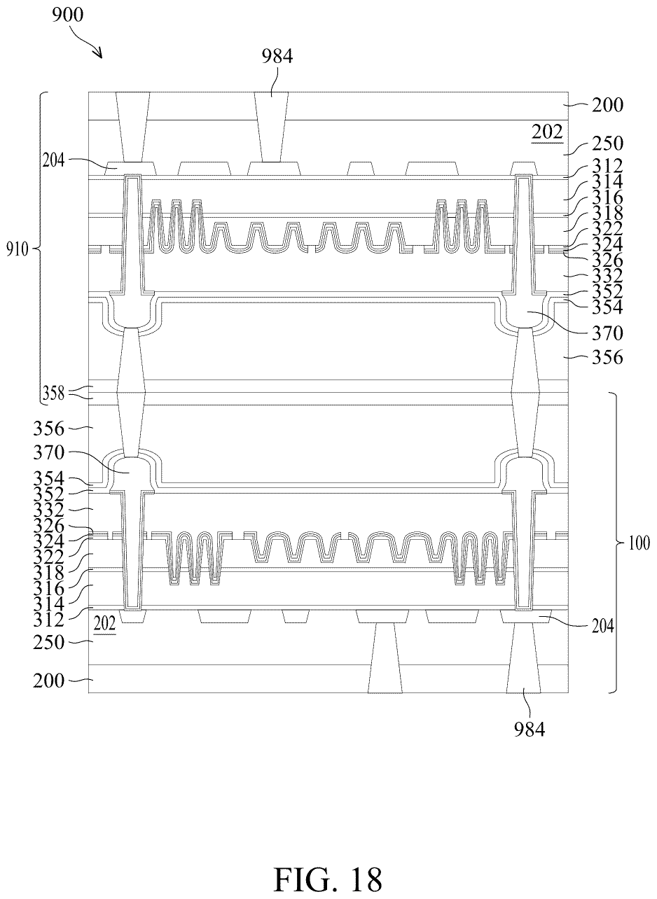

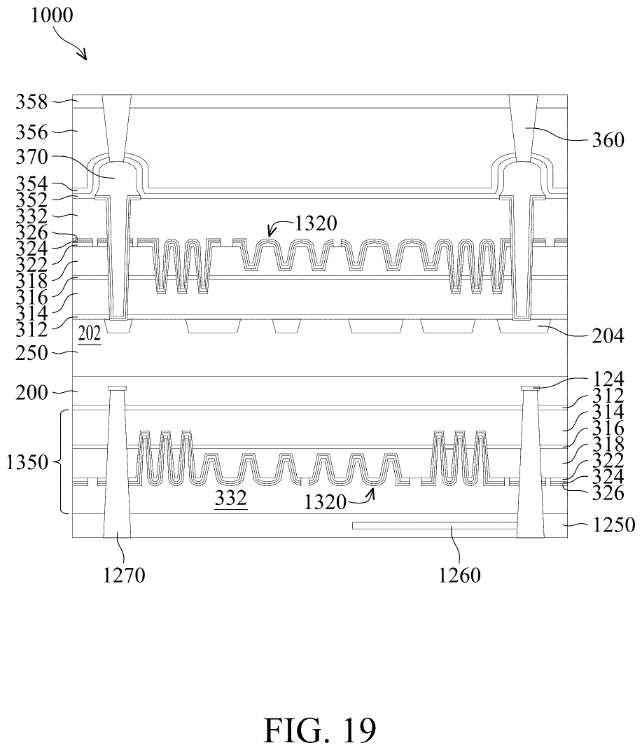

FIG. 18 illustrates a cross-sectional view of a semiconductor package 900, in accordance with some embodiments. In the semiconductor package 900, the semiconductor device 100 is bonded to another semiconductor device 100 by direct bonding. In FIG. 18, semiconductor device 100 may include a bonding structure 360 having a top surface level with the bonding layer 358, and the semiconductor device 100 may also include a metal bonding structure 980 having a top surface level with a bonding layer 858. The bonding structures 360 in the semiconductor devices 100 may be bonded by direct contact with metal-metal bonding. The bonding layers 358 of the semiconductor devices 100 may be bonded by covalent bonds, such as oxide-oxide bonds. Although two semiconductor devices 100 are used as an example for illustrating the semiconductor package 910, any of the semiconductor devices 100 may be replaced with the semiconductor device 400, 500, 600, 700, 800 or other suitable semiconductor devices, with or without forming the capacitor structures 320 in the passivation structure 300. Although not specifically illustrate in device layer 200 in FIG. 1, through substrate vias 982 that penetrate through the substrate 102 to electrically couple the device layer 200 to external components may be implemented either in the semiconductor device 100 or other suitable semiconductor devices.

FIG. 19 illustrates a cross-sectional view of a semiconductor device 1000, in accordance with some embodiments. In the semiconductor device 1000, the first passivation structure 1350 and the capacitor structures 1320 may be disposed at the backside of the device layer 200 (or the backside of the substrate 102). The capacitor structures 1320 may be similar with the capacitor structures 320 and may be formed by similar methods. The first passivation structure 1350 may be similar with first passivation structure 310 and may be formed by similar methods. For example, the first passivation structure 1350 and the capacitor structure 1320 may be vertically reversed as compared to the first passivation structure 310 and the capacitor structure 320, respectively.

A backside interconnect structure 1250 may be disposed below the first passivation structure 1350 and the capacitor structures 1320 to provide power supply and/or additional signal connection to the device layer 200, in accordance with some embodiments. Conductive through vias 1270 may penetrate through the backside interconnect structure 1250, the capacitor structures 1320, the first passivation structure 1350 to be electrically coupled to the components in the device layer 200. The backside interconnect structure 1250 may include conductive features disposed in dielectric layers, similar to the interconnect structure 250. The conductive through vias 1270 penetrate through the first passivation structure 1350 and physically and/or electrically coupled to the source/drain regions 124 in the device layer 200. In addition, the backside interconnect structure 1250, may be formed on the backside of the device layer 200 to provide power supply and/or additional signal connection to the device layer 200. The backside interconnect structure 1250 may include power rails 1260, which are conductive lines that electrically connect the source/drain regions 124 in the device layer 200 to a reference voltage, a supply voltage, or the like. By placing power rails on the backside of the semiconductor device 100 rather than on the front side of the semiconductor device 100, advantages may be achieved. For example, a gate density in the device layer 200 and/or an interconnect density in the interconnect structure 250 may be increased. Further, the backside of the semiconductor device 100 may accommodate wider power rails, reducing resistance and increasing the efficiency of power delivery to the semiconductor device 100. For example, a width of the power rails 1260 may be at least twice a width of first level of conductive lines 206 of the interconnect structure 250. Disposing the capacitor structures 1320 at the backside of the device layer 200 also provides advantages. The capacitor structures 1320 may be electrically coupled to the power rails 1260 and/or the back through vias 1270 that are physically and/or electrically coupled to source/drain regions 124 to regulate the large current provided from the conductive through vias 1270 and/or power rails 1260 before the large current transfers to the source/drain regions 124, thereby protecting the devices (e.g., source/drain regions 124) in the device layer 200 from being damaged by a large pulse.

A semiconductor device including a capacitor structure is provided, in accordance with some embodiments. The semiconductor device may include hole-type capacitors and trench-type capacitors formed in a passivation structure over an interconnect structure. The hole-type capacitor includes layers extending into holes, and the trench-type capacitor includes layers extending into the trenches. The hole-type capacitors may generate less stress in the semiconductor device, and the trench-type capacitors may be disposed in areas with small dimensions. The passivation structure may include an etch stop layer being at least located where the trenches are to be formed. The etch stop layer may partially or completely resist the etch process for forming the trenches. As a result, although the etch process may have a greater etch rate in forming trenches than that in forming the holes, the trenches may be distant from and not damage the underlying interconnect structure when the holes reach to their desired depth. Accordingly, the semiconductor device can contain and form the hole-type capacitors and the trench-type capacitors simultaneously with improved manufacturing yield. In addition, a semiconductor package and a semiconductor device with backside interconnect structure containing the capacitor structure are also provided.

In an embodiment, a semiconductor device is provided. The semiconductor device includes an interconnect structure disposed over a substrate, wherein the interconnect structure includes a conductive feature disposed in a dielectric layer; a first passivation layer disposed over the interconnect structure, wherein a dielectric constant of the first passivation layer is greater than a dielectric constant of the dielectric layer; an etch stop layer disposed over the first passivation layer; a second passivation layer disposed over the etch stop layer; a plurality of holes and a plurality of trenches extending from an upper surface of the second passivation layer into the second passivation layer, wherein at least one of the holes includes a first width in a first direction and a second width in a second direction perpendicular to the first direction, and wherein at least one of the trenches includes a third width smaller than the first width in the first direction and a fourth width greater than the second width in the second direction, wherein the trenches overlap the etch stop layer in a plan view; a first capacitor structure including a first conductive layer, a first insulating layer, and a second conductive layer disposed over the second passivation layer and extending into the holes, wherein the second conductive layer is over the first conductive layer and the first insulating layer, and at least a portion of the second conductive layer over the upper surface of the second passivation layer has a curved top surface; and a second capacitor structure including a third conductive layer, a second insulating layer, and a fourth conductive layer disposed over the second passivation layer and extending into the trenches. In an embodiment, the bottom of the first conductive layer is above the etch stop layer, and the bottom of the third conductive layer is below the etch stop layer. In an embodiment, the third conductive layer is in contact with the etch stop layer, and the first conductive layer is separated from the etch stop layer by the second passivation layer. In an embodiment, the semiconductor device further includes a conductive through via penetrating through the second passivation layer, the first passivation layer, and one of the first capacitor structure or the second capacitor structure to be electrically coupled to the conductive feature of the interconnect structure. In an embodiment, the conductive through via is laterally surrounded by the etch stop layer with a lateral gap therebetween, wherein the lateral gap is filled with the second passivation layer. In an embodiment, the etch stop layer includes a metal material or a conductive metal nitride material. In an embodiment, the holes do not overlap the etch stop layer in the plan view.

In an embodiment, a semiconductor device is provided. The semiconductor device include a device disposed over a substrate, wherein the device includes source/drain features, and each of the source/drain features includes a plurality of layers containing same semiconductor material with different concentrations; a first dielectric layer disposed over the device; an etch stop layer disposed over the first dielectric layer; a second dielectric layer disposed over the etch stop layer; a plurality of holes and a plurality of trenches extending from an upper surface of the second dielectric layer extending into the second dielectric layer, wherein the holes are disposed in a first region, and the trenches are disposed in a second region, wherein at least one of the holes includes a first width in a first direction and a second width in a second direction perpendicular to the first direction, and at least one of the trenches includes a third width in the first direction and a fourth width in the second direction, wherein a difference between the first width and the second width is smaller than a difference between the third width and the fourth width; and a capacitor structure including a first conductive layer, an insulating layer, and a second conductive layer disposed over the upper surface of the second dielectric layer and extending into the holes and the trenches, wherein a first footprint of the first region is greater than a second footprint of the second region. In an embodiment, the trenches have bottoms lower than the bottoms of the holes. In an embodiment, the semiconductor device further includes a conductive through via penetrating through the capacitor structure, and the second region is interposed between the conductive through via and the first region. In an embodiment, the conductive through via is laterally surrounded by the first region and the second region. In an embodiment, the trenches have bottoms lower than the etch stop layer, and the holes have bottoms above the etch stop layer. In an embodiment, the second dielectric layer has a smaller thickness than the first dielectric layer. In an embodiment, the semiconductor device further includes: an insulating filling layer disposed over the capacitor structure and the second dielectric layer; a passivation structure disposed over the insulating filling layer, wherein the conductive through via penetrates through the insulating layer and includes a protrusion extending in the passivation structure; and a conductive bonding structure disposed in the passivation structure, wherein the conductive bonding structure is exposed from the passivation structure and electrically coupled to the conductive through via.

In an embodiment, a method for forming a semiconductor device is provided, the method including: forming an interconnect structure over a substrate, wherein the interconnect structure includes a conductive feature disposed in a dielectric layer; forming a first passivation layer over the interconnect structure, wherein a dielectric constant of the first passivation layer is greater than a dielectric constant of the dielectric layer; forming an etch stop layer over the first passivation layer; forming a second passivation layer over the etch stop layer; performing an etch process to form a plurality of holes and a plurality of trenches in the second passivation layer, wherein at least one of the holes includes a first width in a first direction and a second width in a second direction perpendicular to the first direction, and at least one of the trenches includes a third width smaller than the first width in the first direction and a fourth width greater than the second width in the second direction; and forming a first capacitor structure and a second capacitor structure over the second passivation layer, wherein the first capacitor structure includes a first conductive layer, a first insulating layer, and a second conductive layer extending into the holes, wherein the second conductive layer is disposed over the first conductive layer and the first insulating layer, and at least a portion of the second conductive layer of the second passivation layer has a curved top surface, wherein the second capacitor structure includes a third conductive layer, a second insulating layer, and a fourth conductive layer extending into the trenches, wherein the trenches overlap the etch stop layer in a plan view. In an embodiment, the etch process has a first etch rate in forming the holes and a second etch rate in forming the trenches, wherein the second etch rate is greater than the first etch rate. In an embodiment, during the etch process, when the trenches penetrate through the etch stop layer, the holes have a distance from the etch stop layer. In an embodiment, forming the etch stop layer includes: depositing a layer over the first passivation layer; and patterning the layer. In an embodiment, patterning the layer including removing a first portion of the layer that overlaps the holes in a plan view. In an embodiment, the etch stop layer includes a metal material or a conductive metal nitride material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
an interconnect structure over a substrate, wherein the interconnect structure comprises a conductive feature disposed in a dielectric layer;
a first passivation layer disposed over the interconnect structure, wherein a dielectric constant of the first passivation layer is greater than a dielectric constant of the dielectric layer;
an etch stop layer disposed over the first passivation layer;
a second passivation layer disposed over the etch stop layer;
a plurality of holes and a plurality of trenches extending from an upper surface of the second passivation layer into the second passivation layer, wherein at least one of the holes comprises a first width in a first direction and a second width in a second direction perpendicular to the first direction, and wherein at least one of the trenches comprises a third width smaller than the first width in the first direction and a fourth width greater than the second width in the second direction, wherein the trenches overlap the etch stop layer in a plan view;
a first capacitor structure comprising a first conductive layer, a first insulating layer, and a second conductive layer disposed over the second passivation layer and extending into the holes, wherein the second conductive layer is over the first conductive layer and the first insulating layer, and at least a portion of the second conductive layer over the upper surface of the second passivation layer has a curved top surface; and
a second capacitor structure comprising a third conductive layer, a second insulating layer, and a fourth conductive layer disposed over the second passivation layer and extending into the trenches.

2. The semiconductor device of claim 1, wherein the bottom of the first conductive layer is above the etch stop layer, and the bottom of the third conductive layer is below the etch stop layer.

3. The semiconductor device of claim 1, wherein the third conductive layer is in contact with the etch stop layer, and the first conductive layer is separated from the etch stop layer by the second passivation layer.

4. The semiconductor device of claim 1, further comprising a conductive through via penetrating through the second passivation layer, the first passivation layer, and one of the first capacitor structure or the second capacitor structure to be electrically coupled to the conductive feature of the interconnect structure.

5. The semiconductor device of claim 1, wherein the conductive through via is laterally surrounded by the etch stop layer with a lateral gap therebetween, wherein the lateral gap is filled with the second passivation layer.

6. The semiconductor device of claim 5, wherein the etch stop layer comprises a metal material or a conductive metal nitride material.

7. The semiconductor device of claim 1, wherein the holes do not overlap the etch stop layer in the plan view.

8. A semiconductor device, comprising:
a device disposed over a substrate, wherein the device comprises source/drain features, and each of the source/drain features comprises a plurality of layers containing same semiconductor material with different concentrations;
a first dielectric layer disposed over the device;
an etch stop layer disposed over the first dielectric layer;
a second dielectric layer disposed over the etch stop layer;
a plurality of holes and a plurality of trenches extending from an upper surface of the second dielectric layer extending into the second dielectric layer, wherein the holes are disposed in a first region, and the trenches are disposed in a second region, wherein at least one of the holes comprises a first width in a first direction and a second width in a second direction perpendicular to the first direction, and at least one of the trenches comprises a third width in the first direction and a fourth width in the second direction, wherein a difference between the first width and the second width is smaller than a difference between the third width and the fourth width; and
a capacitor structure comprising a first conductive layer, an insulating layer, and a second conductive layer disposed over the upper surface of the second dielectric layer and extending into the holes and the trenches, wherein a first footprint of the first region is greater than a second footprint of the second region.

9. The semiconductor device of claim 8, wherein the trenches have bottoms lower than the bottoms of the holes.

10. The semiconductor device of claim 8, further comprising a conductive through via penetrating through the capacitor structure, and the second region is interposed between the conductive through via and the first region.

11. The semiconductor device of claim 10, wherein the conductive through via is laterally surrounded by the first region and the second region.

12. The semiconductor device of claim 8, wherein the trenches have bottoms lower than the etch stop layer, and the holes have bottoms above the etch stop layer.

13. The semiconductor device of claim 8, wherein the second dielectric layer has a thickness smaller than a thickness of the first dielectric layer.

14. The semiconductor device of claim 8, further comprising:
an insulating filling layer disposed over the capacitor structure and the second dielectric layer;
a passivation structure disposed over the insulating filling layer, wherein the conductive through via penetrates through the insulating layer and comprises a protrusion extending in the passivation structure; and
a conductive bonding structure disposed in the passivation structure, wherein the conductive bonding structure is exposed from the passivation structure and electrically coupled to the conductive through via.

15. A method for forming a semiconductor device, the method comprising:
forming an interconnect structure over a substrate, wherein the interconnect structure comprises a conductive feature disposed in a dielectric layer;
forming a first passivation layer over the interconnect structure, wherein a dielectric constant of the first passivation layer is greater than a dielectric constant of the dielectric layer;
forming an etch stop layer over the first passivation layer;
forming a second passivation layer over the etch stop layer;
performing an etch process to form a plurality of holes and a plurality of trenches in the second passivation layer, wherein at least one of the holes comprises a first width in a first direction and a second width in a second direction perpendicular to the first direction, and at least one of the trenches comprises a third width smaller than the first width in the first direction and a fourth width greater than the second width in the second direction; and
forming a first capacitor structure and a second capacitor structure over the second passivation layer, wherein the first capacitor structure comprises a first conductive layer, a first insulating layer, and a second conductive layer extending into the holes, wherein the second conductive layer is disposed over the first conductive layer and the first insulating layer, and at least a portion of the second conductive layer of the second passivation layer has a curved top surface, wherein the second capacitor structure comprises a third conductive layer, a second insulating layer, and a fourth conductive layer extending into the trenches, wherein the trenches overlap the etch stop layer in a plan view.

16. The method of claim 15, wherein the etch process has a first etch rate in forming the holes and a second etch rate in forming the trenches, wherein the second etch rate is greater than the first etch rate.

17. The method of claim 15, wherein during the etch process, when the trenches penetrate through the etch stop layer, the holes have a distance from the etch stop layer.

18. The method of claim 15, wherein forming the etch stop layer comprises:
depositing a layer over the first passivation layer; and
patterning the layer.

19. The method of claim 18, wherein patterning the layer comprising removing a first portion of the layer that overlaps the holes in a plan view.

20. The method of claim 15, wherein the etch stop layer comprises a metal material or a conductive metal nitride material.
